(19) United States
(12) Patent Application Publication
(10) Pub. No.: US 2025/0221283 A1
(43) Pub. Date: Jul. 3, 2025

(54) DISPLAY DEVICE

(71) Applicant: LG Display Co., Ltd., Seoul (KR)

(72) Inventor: HyunSik CHOI, Changwon-si (KR)

(21) Appl. No.: 18/886,060

(22) Filed: Sep. 16, 2024

(30) Foreign Application Priority Data
Dec. 28, 2023 (KR) 10-2023-0194861

(51) Int. Cl. H10K 59/80; H10K 59/12; H10K 59/126; H10K 59/95

(52) U.S. Cl. CPC H10K 59/8791; H10K 59/126; H10K 59/95; H10K 59/1201

(57) ABSTRACT

Provided is a display device. The display device may include a display panel including an active area in which a plurality of sub pixels is disposed and a sensor area which is disposed in the active area and has a first hole disposed therein, a front member disposed on a top surface of the display panel, a support member disposed on a rear surface of the display panel, a conductive member disposed on a rear surface of the support member and a conductive light shielding member which is disposed between the conductive member and the support member in a first region corresponding to the support member and covers an edge of a rear surface of the front member exposed by the first hole and an inner side surface of the first hole in a second region corresponding to an edge of the first hole.

### CROSS-REFERENCE TO RELATED APPLICATIONS

This application claims the priority of Korean Patent Application No. 10-2023-0194861 filed on Dec. 28, 2023, in the Korean Intellectual Property Office, the disclosure of which is incorporated herein by reference.

### BACKGROUND

### Technical Field

The present disclosure relates to a display device.

### Description of the Related Art

As the information society develops, demands for display devices which display images is increasing and various types of display devices such as a liquid crystal display device and an organic light emitting display device are utilized.

As display devices which are used for a monitor of a computer, a television, or a cellular phone, there are an organic light emitting display (OLED) device which is a self-emitting device, a liquid crystal display (LCD) device which requires a separate light source, and the like.

An applicable range of the display device is diversified to personal mobile devices as well as monitors of computers and televisions and a display device with a large display area and a reduced volume and weight is being studied.

Further, in order to provide more various functions to the users, the display device also provides an optical component, such as a camera and a proximity sensor together. However, the optical component, such as a camera, needs to be exposed to the outside to recognize light so that a display device in which the optical component is disposed by notching a part of the display device or forming a hole in the display device is being developed.

### BRIEF SUMMARY

An object to be achieved by the present disclosure is to provide a display device which improves light leakage and electrostatic discharge (ESD) caused by disposing an electronic component, such as a camera or a sensor in an active area.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device may include a display panel including an active area in which a plurality of sub pixels is disposed and a sensor area which is disposed in the active area and has a first hole disposed therein, a front member disposed on a top surface of the display panel, a support member disposed on a rear surface of the display panel, a conductive member disposed on a rear surface of the support member and a conductive light shielding member which is disposed between the conductive member and the support member in a first region corresponding to the support member and covers an edge of a rear surface of the front member exposed by the first hole and an inner side surface of the first hole in a second region corresponding to an edge of the first hole.

According to another aspect of the present disclosure, a display device may include a display panel including an active area in which a plurality of sub pixels is disposed and a sensor area which is disposed in the active area and has a first hole disposed therein, a front member disposed on a top surface of the display panel, a support member disposed on a rear surface of the display panel, a conductive member disposed on a rear surface of the support member and a conductive light shielding member which includes a first part disposed on a rear surface of the support member and a second part which extends from an edge of the support member to an edge of a rear surface of the front member exposed by the first hole.

Other detailed matters of the exemplary embodiments are included in the detailed description and the drawings.

According to the exemplary embodiment of the present disclosure, an electronic component, such as a camera or a sensor, is disposed in the active area, but the light leakage or the ESD to be caused by disposing the electronic component may be minimized.

According to the exemplary embodiment of the present disclosure, an opaque conductive material is used in a hole area to minimize light leakage and ESD.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1A is a plan view of a display device according to an exemplary embodiment of the present disclosure;

FIG. 1B is an enlarged plan view of a display device of FIG. 1A;

FIG. 2 is a cross-sectional view taken along the line I-I′ of FIGS. 1A and 1B.

FIGS. 3A to 3C are cross-sectional views of a conductive light shielding member of a display device according to various exemplary embodiments of the present disclosure; and

FIGS. 4A to 4D are views of a manufacturing method of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

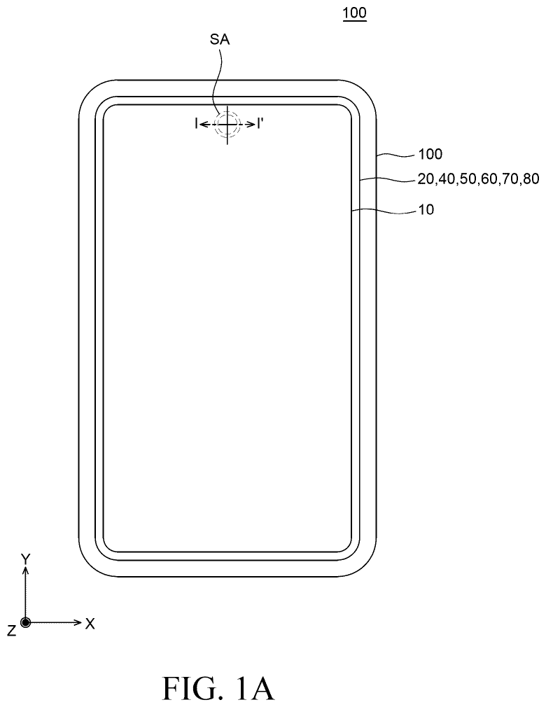

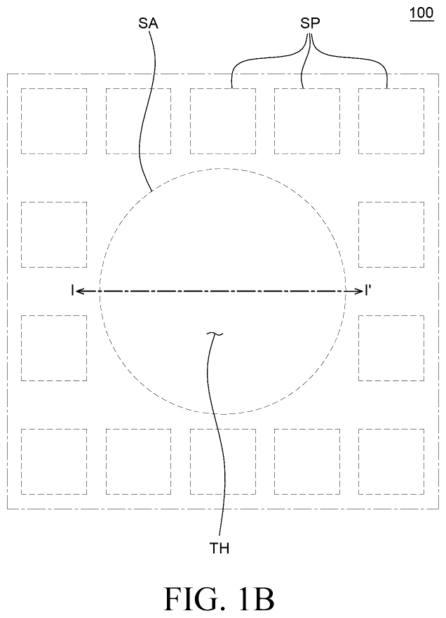

FIG. 1A is a plan view of a display device according to an exemplary embodiment of the present disclosure and FIG. 1B is an enlarged plan view of a display device of FIG. 1A;

Referring to FIGS. 1A and 1B, a display panel 40 of the display device 100 is a panel in which images are implemented. Display elements for implementing images, and circuits, wiring lines, and components for driving the display elements may be disposed in the display panel. The display panel 40 may include an active area, a non-active area, and a sensor area SA.

The active area is an area where a plurality of sub pixels SP is disposed to display images. Each of the plurality of sub pixels SP is an individual unit which emits light and in each of the plurality of sub pixels SP, a light emitting diode and a driving circuit may be formed. For example, in the plurality of sub pixels SP, a display element for displaying images and a circuit unit for driving the display element may be disposed. For example, when the display device 100 is an organic light emitting display device, the display element may include an organic light emitting diode and when the display device 100 is a liquid crystal display device, the display element may include a liquid crystal element. The plurality of sub pixels SP may include a red sub pixel SP, a green sub pixel SP, a blue sub pixel SP and/or a white sub pixel SP, but is not limited thereto.

The non-active area is an area where no image is displayed and various wiring lines and driving ICs for driving the plurality of sub pixels SP disposed in the active area may be disposed. For example, in the non-active area, various ICs such as a gate driver IC and a data driver IC and driving circuits may be disposed, but is not limited thereto. A non-active area in which an image is not displayed may be a bezel area and exemplary embodiments of the present disclosure are not limited thereto.

The non-active area may be an area which encloses the active area. For example, the non-active area may be an area extending from the active area or an area in which the plurality of sub pixels SP is not disposed, but it is not limited thereto.

The sensor area SA may be disposed in the active area. In the active area, the sensor area SA may be disposed between the plurality of sub pixels SP. The sensor area SA may be an area in which an optical sensor component, such as a camera or a proximity sensor, is disposed. The sensor area SA may include a through hole TH which passes through some configurations of the display device 100 to dispose the optical components. The through hole TH which passes through the display panel 40 is formed to ensure a space in which the optical sensor component, etc., is disposed.

Some of light emitted from the plurality of sub pixels SP may travel toward the sensor area SA disposed between the plurality of sub pixels SP, for example, the through hole TH. When the light from the plurality of sub pixels SP traveling to the through hole TH is transmitted to the optical sensor component such as a camera or a proximity sensor, the noise is generated, which may degrade the reliability of the optical component. A light shielding film may be disposed in the through hole TH so as not to transmit the light emitted from the plurality of sub pixels SP into the through hole TH. The light shielding film may be a shielding layer or a light shielding member, but is not limited to the terminology.

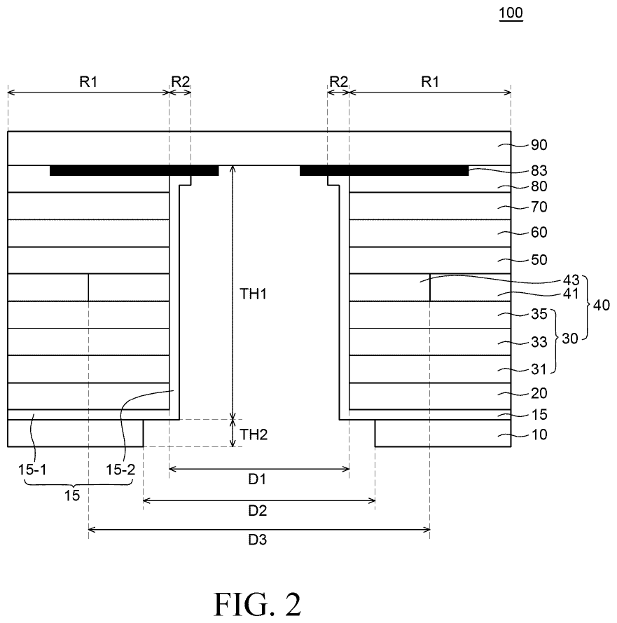

FIG. 2 is a cross-sectional view taken along the line I-I′ of FIGS. 1A and 1B.

Referring to FIG. 2, the display device 100 according to the exemplary embodiment of the present disclosure may include a front member 90, an adhesive layer 80, an optical layer 70, a touch layer 60, an encapsulation layer 50, a display panel 40, a support member 20, and a conductive member 10.

The front member 90 may be disposed on a top surface of the display panel 40. The front member 90 may protect the optical layer 70 and the display panel 40 disposed below the front member 90 from external impact, moisture, and heat. The front member 90 may be formed of a material having an impact resistance and optical transmittance. For example, the front member 90 may be a substrate formed of glass or a film formed of a plastic material such as polymethylmethacrylate (PMMA), polyimide (PI), or polyethylene terephthalate (PET), but is not limited thereto. The front member 90 may be a window cover, a cover window, or a cover glass, but is not limited to the terminology.

The optical layer 70 may be disposed between the front member 90 and the display panel 40. The optical layer 70 selectively transmits light to reduce the reflection of external light which is incident onto the display panel 40. For example, the display panel 40 includes various metal materials applied to a thin film transistor, a wiring line, an electroluminescent element, and the like. Accordingly, the external light incident onto the display panel 40 may be reflected from the metal material so that the visibility of the display device 100 may be reduced due to the reflection of the external light. Therefore, the optical layer 70 is disposed on one surface of the display panel 40 to suppress the reflection of the external light and increase an outdoor visibility of the display device 100. The metal layer 70 converts the polarization of the external light which is reflected by metal to improve visibility and a contrast ratio. The optical layer 70 may be implemented as a polarizer or a circular polarizer in which a linear polarizer and a phase retardation film are bonded, but is not limited thereto.

The adhesive layer 80 is formed between the optical layer 70 and the front member 90 to bond the front member 90 onto the optical layer 70. The adhesive layer 80 may be configured by a material having adhesiveness. For example, the adhesive layer 80 may be configured by an optical clear adhesive (OCA), a pressure sensitive adhesive (PSA), or the like, but is not limited thereto.

The display panel 40 is a panel in which an image is implemented and may be configured by disposing a light emitting unit 41 in which a plurality of display elements which implements an image, a circuit for driving the display element, a wiring line, and a component are disposed, on the substrate 30. For example, when the display device 100 is an organic light emitting display device, the display element in the light emitting unit 41 may include an organic light emitting diode.

The light emitting unit 41 may be formed on the substrate 30. The substrate 30 may be configured by plastic, such as polymer or polyimide (PI) or glass. The substrate 30 may be configured as a single layer or a plurality of layers. For example, the substrate may be configured as a first substrate 31 or configured as a plurality of layers by laminating one or more second substrates 35 on the first substrate 31. When the substrate 30 is configured as a plurality of layers, an inorganic insulating layer (inter-PI dielectric) 33 may be disposed between the substrates.

The light emitting unit 41 is disposed on the substrate 30 and may include a driving element layer in which driving elements configured by a plurality of transistors are disposed and a light emitting diode layer disposed on the driving element layer. The driving element is a driving element for driving a light emitting diode of the active area and may use a transistor. The transistor includes an active layer, a gate electrode, a source electrode, and a drain electrode. The transistor which is used as the driving element may have a top gate structure or a bottom gate structure depending on the placement position of the gate electrode, but is not limited thereto.

The transistor layer may drive each sub pixel SP which includes a light emitting diode layer by means of driving data signals received from the outside. The light emitting diode layer may operate to emit light according to a driving current or voltage formed by the driving element. The light emitting diode layer may be configured by a light emitting diode including an anode electrode which is electrically connected to the driving element layer, an emission material formed on the anode electrode, and a cathode electrode which is electrically connected to the emission material.

The light emitting diode in each sub pixel SP in the light emitting unit 41 is vulnerable to external moisture or oxygen so that an encapsulation layer 50 which suppresses permeation of external moisture or oxygen into the light emitting diode may be disposed on the display panel 40. The encapsulation layer 50 may be disposed so as to cover the light emitting diodes.

The encapsulation layer 50 is formed on the display panel 40 so as to enclose the active area to suppress oxygen or moisture from permeating to the light emitting diode layer of the light emitting unit 41. The encapsulation layer 50 according to the exemplary embodiment of the present disclosure may be formed with a double-layered structure in which an organic material layer and an inorganic material layer are alternately laminated, but is not limited thereto. The inorganic material layer may block the oxygen or moisture from permeating the light emitting diode layer of the light emitting unit 41. The organic material layer may be formed to have a thickness larger than that of the inorganic material layer to cover foreign particles which may be generated during the manufacturing process, but is not limited thereto. For example, the encapsulation layer 50 may include a first inorganic film, an organic film on the first inorganic film, and a second inorganic film on the organic film. The organic film may be a foreign particle cover layer, but is not limited by the terminology.

The touch layer 60 may be disposed on the encapsulation layer 50 or may be disposed on a rear surface of the display panel 40 or may be disposed in the display panel 40. When the panel type touch sensor is coupled, the thickness and/or width of the display device 100 may be increased. Therefore, studies are conducted to dispose the touch sensor inside the display device 100 and as one method, a structure in which a touch sensing unit is disposed on the encapsulation layer 50 is derived. This type of built-in touch sensor is also called a touch-sensor on encapsulation (ToE).

A structure of the touch layer 60 will be described in more detail below. A touch buffer film may be disposed on the encapsulation layer 50. A touch sensor may be disposed on the touch buffer film and the touch sensor may include touch sensor metals and a bridge metal which are disposed on different layers. A touch interlayer insulating film may be disposed between the touch sensor metals and the bridge metal. For example, the touch sensor metals may include a first touch sensor metal, a second touch sensor metal, and a third touch sensor metal which are disposed to be adjacent to each other.

When the third touch sensor metal is disposed between the first touch sensor metal and the second touch sensor metal and the first touch sensor metal and the second touch sensor metal need to be electrically connected, the first touch sensor metal and the second touch sensor metal may be electrically connected by means of the bridge metal disposed on a different layer. The bridge metal may be insulated from the third touch sensor metal by the touch interlayer insulating film. The protection layer may be disposed while covering the touch sensor. The protection layer may be an organic insulating film, but is not limited to the material.

The support member 20 may be disposed below the display panel 40. When the substrate 30 which forms the display panel 40 is formed of a plastic material, such as polyimide, a support substrate formed of glass is disposed below the substrate 30 to perform the manufacturing process of the display device 100 and a component, such as an optical layer 70 is formed on the display panel 40. Thereafter, the support substrate may be released. However, a component for supporting the substrate is necessary even after releasing the support substrate, so that the support member 20 for supporting the substrate may be disposed below the display panel 40.

The support member 20 not only supports the display panel 40, but also protects the display panel 40 from moisture, heat, and impacts. The support member 20 may be a film formed of polyimide (PI), polyethylene terephthalate (PET), or polyethylene naphthalate (PEN), but is not limited thereto. The support member 20 may be a back plate, a first plate, or a hard plate, but is not limited to the terminology.

A conductive member 10 may be disposed below the support member 20. The conductive member 10 may protect and support the structure on the conductive member 10. The conductive member 10 is formed of a rigid material to minimize dents caused by the external impact. The conductive member 10 may serve as a heat dissipation member which discharges heat generated while driving the display device 100. The conductive member 10 is formed of a material having excellent electric conductivity to discharge static electricity generated in the front member 90 to the outside.

The conductive member 10 may be configured by a material having excellent heat conductivity and electric conductivity. For example, the conductive member 10 may be a material including copper (Cu) or graphite, but is not limited thereto. The conductive member 10 may be a metal plate, a second plate, or a rigid member, but is not limited by the terminology.

A through hole TH may be formed in the remaining configuration excluding the front member 90, among configurations of the display device 100. The through hole TH may be formed by passing through the adhesive layer 80, the optical layer 70, the touch layer 60, the encapsulation layer 50, the display panel 40, the support member 20, and the conductive member 10. The through hole TH may be a space for placing optical components, such as a camera, in the active area, or an empty space.

The optical component may be disposed in the through hole TH to recognize an external environment at the outside of the front member 90. The optical component may operate by recognizing external light which is transmitted to the optical component through the front member 90. The through hole TH is not formed in the front member 90 to suppress the permeation of foreign particles, etc., into the through hole TH.

A size of the through hole TH of the conductive member 10 may vary depending on an order of an attaching process of the conductive member 10 and a forming process of the through hole TH. Hereinafter, a through hole TH which is continuously formed in the adhesive layer 80, the optical layer 70, the touch layer 60, the encapsulation layer 50, the display panel 40, and the support member 20, for example, a through hole disposed along the adhesive layer 80, the optical layer 70, the touch layer 60, the encapsulation layer 50, the display panel 40, and the support member 20 is referred to as a first hole TH1. A through hole formed in the conductive member 10 is referred to as a second hole TH2.

The first hole TH1 having a first diameter D1 is formed in the adhesive layer 80, the optical layer 70, the touch layer 60, the encapsulation layer 50, the display panel 40, and the support member 20 at one time. Thereafter, the conductive member 10 with the second hole TH2 having a second diameter D2 formed therein may be attached on a rear surface of the support member 20. For example, the first diameter D1 of the first hole TH1 may be smaller than the second diameter D2 of the second hole TH2. If the second hole TH2 is smaller than the first hole TH1, when the conductive member 10 is attached, it may be difficult to align the second hole TH2 and the first hole TH1 or it may be difficult to form the first member 120 to be described below in the first hole TH1. Accordingly, when the through hole TH is formed before attaching the conductive member 10, the adhesive layer 80, the optical layer 70, the touch layer 60, the encapsulation layer 50, the display panel 40, and the support member 20 in which the first hole TH1 is formed and the conductive member 10 with the second hole TH2 having a diameter larger than that of the first hole TH1 are attached to manufacture the display device 100.

The light emitting diode in each sub pixel SP in the light emitting unit 41 of the display panel 40 is vulnerable to external moisture or oxygen so that the encapsulation layer 50 which suppresses permeation of external moisture or oxygen into the light emitting diode may be disposed on the display panel 40.

The driving element layer of the light emitting unit 41 may be configured over the active area and the non-active area, but the light emitting diode layer may be configured only in the active area. The non-active area in which the image is not displayed may be an outer bezel area (not illustrated) or a second bezel area. In the outer bezel area (not illustrated), a part of the driving element layer and a part of the encapsulation layer 50 which covers a side surface of the light emitting diode layer in the active area may be disposed.

The through hole TH is formed in the display panel 40. If in the position where the through hole TH is formed and surroundings thereof, the driving element layer and the light emitting diode layer having the same shape as an area of the light emitting unit 41 in which the through hole TH is not formed are disposed, the external moisture or oxygen may permeate the light emitting diode through a side surface in which the through hole is formed. In order to suppress this problem, a donut-shaped inner bezel area 43 or a first bezel area may be disposed in the surroundings of the through hole of the light emitting unit 41.

In the inner bezel area 43, a part of the driving element layer and a part of the encapsulation layer 50 which covers a side surface of the light emitting diode layer in the active area may be disposed. For example, a diameter D3 of the hole in the light emitting diode layer may be larger than the diameter D1 of the first hole TH1. The inner bezel area 43 may have a ring shape extending from an inner surface of the hole in the light emitting diode layer to an inner surface of the first hole TH1, but is not limited to the shape.

Light emitted from the light emitting unit 41 is transmitted to the outside of the display device 100 through the front member 90. The front member 90 may be divided into a light transmitting area and a light shielding area depending on whether to transmit emitted light to the outside. For example, the light emitted from the light emitting unit 41 may be transmitted to the outside through the light transmitting area of the front member 90. For example, the light emitted from the light emitting unit 41 may be blocked from being transmitted to the outside by the light shielding area of the front member 90.

The light shielding area of the front member 90 may be configured by a first light shielding member which encloses the entire outer peripheral portion of the front member 90 and a second light shielding member 83 which is formed in an area in which the front member 90 and the first hole TH1 are in contact with each other. The first light shielding member is configured by a solid line which encloses the entire outer peripheral portion of the front member 90 and may block the light in the active area from being transmitted to the outer peripheral portion of the front member 90. The second light shielding member 83 is configured by a solid line which encloses the outer periphery of the first hole TH1 in the area in which the front member 90 and the first hole TH1 are in contact and may block the light in the active area from being transmitted to the through hole TH or the sensor area SA of the front member 90. The first light shielding member and the second light shielding member 83 are configured on the rear surface of the front member 90 to be coupled to the components including the display panel 40 by means of the adhesive layer 80.

An area of the conductive member 10 may be smaller than an area of the support member 20, the display panel 40, and/or the front member 90 thereabove. Specifically, the area of the conductive member 10 may be smaller than the area of the front member 90. The conductive member 10 may discharge static electricity generated in the front member 90, etc., to the outside. To this end, a connection member which electrically connects the conductive member 10 and the front member 90 or the like is necessary. In order to minimize a space required for the connection of the conductive member 10 and the connection member, the area of the conductive member 10 may be configured to be smaller than the area of the front member 90 or the like.

In the meantime, charges may be generated on the surface of the display device 100, for example, the front member 90, due to physical friction or the like. If the generated charges are not discharged to the outside through a ground path, charges may be mainly accumulated on a side surface of an end portion of the display panel 40 disposed in the bezel area 43 of the display panel 40. When the charges are accumulated in a specific area, an electric field may be formed in proportion to an amount of accumulated charges.

When the charges generated on the surface of the display device 100 are not effectively discharged to the outside, a strong electric field may be formed on the side surface of the end portion of the display panel 40. When the strong electric field is formed on the side surface of the end portion of the display panel 40, the side area of the end portion becomes brighter than the active area of the display panel 40, which affects the reliability of the display device 100.

Referring to FIG. 2 again, a conductive light shielding member 15 may be disposed between the conductive member 10 and the support member 20. The conductive light shielding member 15 may be disposed in a first region R1 corresponding to the support member 20 and a second region R2 corresponding to an edge of the first hole TH1. To be more specific, the conductive light shielding member 15 is disposed between the conductive member 10 and the support member 20 in the first region R1 corresponding to the support member 20. The conductive light shielding member may cover an edge of the rear surface of the front member 90 exposed in the first hole TH1 and an inner side surface of the first hole TH1 in the second region R2 corresponding to the edge of the first hole TH1.

The conductive light shielding member 15 may form a charge movement path which moves charges (for example, ESD charges) generated in the front member 90 from the inner side surface of the first hole TH1 to between the support member 20 and the conductive member 10. The charge movement path may allow the ESD charges generated in the front member 90 to be easily transmitted to the ground and suppress the damage of the display device due to the ESD charges. In the meantime, the conductive light shielding member 15 may be formed by an inkjet method, but there was a limitation in improving the light leakage and ESD with the inkjet method. Therefore, a new conductive light shielding member 15 and a display device 100 including the same will be proposed.

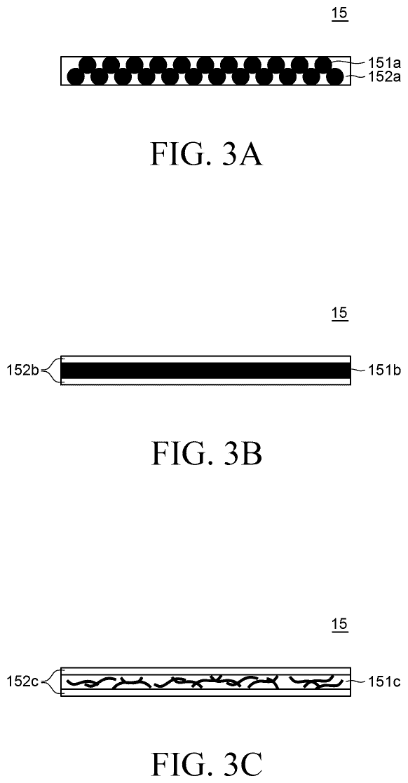

As it will be described below with reference to FIGS. 3A to 3C, the conductive light shielding member 15 may include a plurality of conductive balls, a conductive film, and/or a conductive fabric. Further, the conductive light shielding member 15 may include a material having an adhering property. An adhesive material may be configured by an adhesiveness. For example, the adhesive material may be configured by an optical clear adhesive (OCA) or a pressure sensitive adhesive (PSA), but is not limited thereto. As described above, the conductive light shielding member 15 is mixed with an adhesive material to be disposed between the conductive member 10 and the support member 20.

As the conductive light shielding member 15 is mixed with the adhesive material to be disposed, the conductive light shielding member 15 may adhesively bond the support member 20 and the conductive member 10. In other words, the support member 20 and the conductive member 10 may be bonded to each other by means of the conductive light shielding member 15. The conductive light shielding member 15 has not only conductivity, but also the adhering property to bond two layered elements, that is, the support member 20 and the conductive member 10. After bonding, the conductive material included in the conductive light shielding member 15, for example, the conductive balls, the conductive film, and/or the conductive fabric may improve the light leakage and the ESD.

In the meantime, according to the exemplary embodiment of the present disclosure, the display device 100 further includes an additional light shielding member 83 and the additional light shielding member 83 may be disposed on the rear surface of the front member 90. The additional light shielding member 83 may be, for example, formed with a printing pattern. The additional light shielding member 83 may be disposed in the circumference of the first hole TH1 or around the circumference of the first hole TH1, on the rear surface of the front member. At least one of the first hole TH1 and/or the second hole TH2 may be disposed so as to overlap the additional light shielding member 83.

The additional light shielding member 83 may discharge the ESD charges generated in the front member 90 together with the conductive light shielding member 15. The additional light shielding member 83 may be formed of an insulating material or a conductive material, like the conductive light shielding member 15. For example, the additional light shielding member 83 may be formed of a black ink, or an ink including a conductive material, a silver paste, or the like. Further, the additional light shielding member 83 may also be formed of an insulating material.

According to the exemplary embodiment, an end portion of the conductive light shielding member 15 may be disposed on the additional light shielding member 83 in an area corresponding to the first hole TH1. Specifically, in the area corresponding to the first hole TH1, the end portion of the conductive light shielding member 15 may be disposed on the rear surface of the additional light shielding member 83. As the end portion of the conductive light shielding member 15 is disposed on the rear surface of the additional light shielding member 83, in the area corresponding to the first hole TH1, the additional light shielding member 83 and the conductive light shielding member 15 are in contact with each other. The contact may cause the ESD charges generated in the front member 90 to be discharged via the conductive light shielding member 15 starting from the additional light shielding member 83.

According to the exemplary embodiment, the conductive light shielding member 15 may include a first part 15-1 disposed in the first region R1 and a second part 15-2 disposed in the second region R2. Here, the length of the second part 15-2, for example, a radial length may be longer than a length, for example, a height of the entire laminating unit disposed between the conductive light shielding member 15 and the front member 90. A difference of the length of the second part 15-2 of the conductive light shielding member 15 and a length of the entire laminating unit may be smaller than a radius of the first hole TH1.

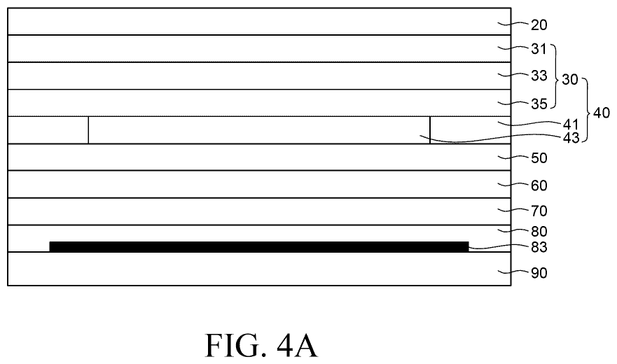

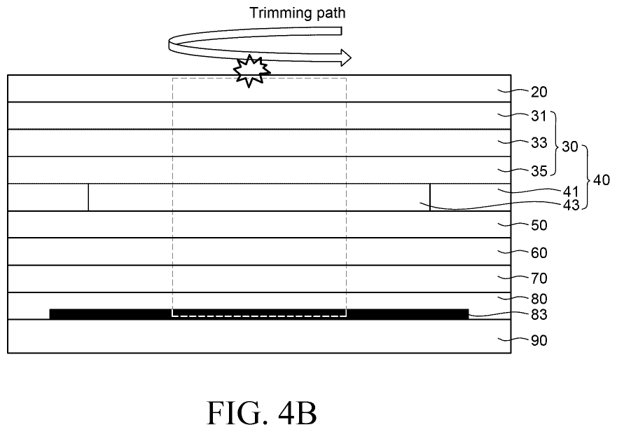

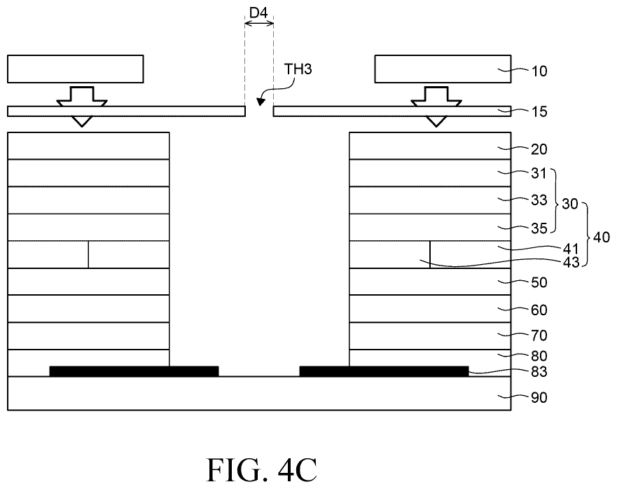

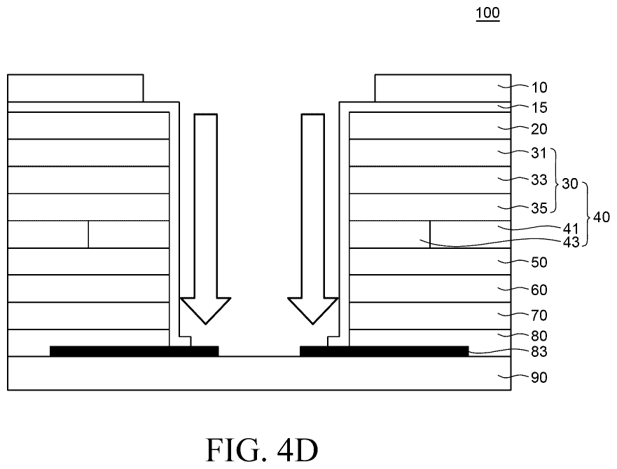

The laminating unit or lamination stack may include the optical layer 70, the touch layer 60, the encapsulation layer 50, the display panel 40, and the support member 20 which are sequentially disposed. The optical layer 70, the touch layer 60, the encapsulation layer 50, the display panel 40, and the support member 20 may form a continuous interface in the inner side surface of the first hole TH1. As it will be described below with reference to FIGS. 4A to 4D, after disposing the laminating unit on the front member 90, a process for forming the first hole TH1 is performed on the laminating unit so that the side surface of the laminating unit has a continuous surface. Therefore, the optical layer 70, the touch layer 60, the encapsulation layer 50, the display panel 40, and the support member 20 which form the laminating unit may have the substantially same radius.

The conductive light shielding member 15 may cover the inner side surface of the laminating unit while being in contact with inner side surfaces of the optical layer 70, the touch layer 60, the encapsulation layer 50, the display panel 40, and the support member 20. The conductive light shielding member 15 is formed after forming the first hole TH1 in the laminating unit so that it may be disposed while covering the inner side surfaces of the plurality of layered elements which forms the laminating unit. The conductive light shielding member 15 is deformed or molded toward the inside of the first hole TH1 by an external force corresponding to a dimension of the first hole TH1 and may cover the inner side surface of the laminating unit.

The conductive member 10 is disposed on the rear surface of the conductive light shielding member 15. The conductive light shielding member 15 and the conductive member 10 are electrically connected and the ESD charges which are transmitted from the conductive light shielding member 15 may be transmitted to the conductive member 10 and may be discharged.

FIGS. 3A to 3C are cross-sectional views of a conductive light shielding member of a display device according to various exemplary embodiments of the present disclosure. Specifically, FIG. 3A illustrates a conductive light shielding member including conductive balls, FIG. 3B illustrates a conductive light shielding member including a conductive film, and FIG. 3C illustrates a conductive light shielding member including a conductive fabric.

Referring to FIG. 3A, the display device 100 according to the exemplary embodiment of the present disclosure may include a conductive light shielding member 15 having a plurality of conductive balls 151a and an adhesive material 152a which stickily binds the plurality of conductive balls 151a. The plurality of conductive balls 151a may be stickily bonded into the adhesive material 152a. The conductive light shielding member 15 bonds the support member 20 and the conductive member 10 by means of the adhesive material 152a and the ESD charge movement path which passes between the support member 20 and the conductive member 10 may be formed.

Referring to FIG. 3B, the display device 100 according to the exemplary embodiment of the present disclosure may include a conductive light shielding member 15 having a conductive film 151b and adhesive materials 152b disposed a top surface and a bottom surface of the conductive film 151b. The support member 20 and the conductive member 10 may be bonded by the conductive light shielding member 15. That is, the conductive light shielding member 15 bonds the support member 20 and the conductive member 10 by means of the adhesive material 152b and the ESD charge movement path which passes between the support member 20 and the conductive member 10 may be formed.

Referring to FIG. 3C, the display device 100 according to the exemplary embodiment of the present disclosure may include a conductive light shielding member 15 having a conductive fabric 151c and adhesive materials 152c disposed on a top surface and a bottom surface of the conductive fabric 151c. The conductive fabric 151c may be formed by weaving or entangling conductive threads. According to the exemplary embodiment, the conductive fabric 151c may be formed by one fabric 151c layer formed by conductive threads and adhesive material 152c may be disposed on a top surface and a bottom surface of the conductive fabric 151c. According to another exemplary embodiment, the conductive fabric 151c may be formed by non-woven conductive threads and the conductive threads may be surrounded by an adhesive material 152c to form the conductive fabric 151c. The support member 20 and the conductive member 10 may be bonded to each other by means of the conductive light shielding member 15. The conductive member 10 and the support member 20 may be bonded to each other by means of the adhesive material 152c which forms the conductive light shielding member 15. The ESD charge movement path which passes between the support member 20 and the conductive member 10 may be formed by the conductive light shielding member 15.

FIGS. 4A to 4D are views of a manufacturing method of a display device according to an exemplary embodiment of the present disclosure.

The display device 100 according to the exemplary embodiment of the present disclosure may include a front member 90, a laminating unit, a conductive light shielding member 15, and a conductive member 10. The laminating unit may include the optical layer 70, the touch layer 60, the encapsulation layer 50, the display panel 40, and the support member 20. Hereinafter, a manufacturing process of the display device 100, and more specifically, a process of manufacturing a part of the display device 100 corresponding to a sensor area SA will be described as an example.

Referring to FIG. 4A, the laminating unit may be disposed on the rear surface of the front member 90. According to the exemplary embodiment, before placing the laminating unit, the additional light shielding member 83 is disposed on the rear surface of the front member 90 and thereafter, the laminating unit may be disposed.

Referring to FIG. 4B, laser and trimming processes may be performed to the rear surface of the laminating unit. Primarily, laser is irradiated toward the rear surface of the laminating unit and then a part in which the first hole TH1 will be formed may be removed by the trimming process. The first hole TH1 having a first diameter D1 may be formed at one time by this process. To be more specific, the first hole TH1 having the first diameter D1 may be formed at one time in the adhesive layer 80, the optical layer 70, the touch layer 60, the encapsulation layer 50, the display panel 40, and the support member 20 by the trimming process.

Referring to FIG. 4C, the conductive member 10 with the second hole TH2 having a second diameter D2 may be attached onto the rear surface of the support member 20. Here, the first diameter D1 of the first hole TH1 may be smaller than the second diameter D2 of the second hole TH2. If the second hole TH2 is smaller than the first hole TH1, when the conductive member 10 is attached, it may be difficult to align the second hole TH2 and the first hole TH1 or it may be difficult to form the first member 120 to be described below in the first hole TH1. When the through hole TH1 is formed before attaching the conductive member 10, the adhesive layer 80, the optical layer 70, the touch layer 60, the encapsulation layer 50, the display panel 40, and the support member 20 in which the first hole TH1 is formed and the conductive member 10 with the second hole TH2 having a diameter larger than that of the first hole TH1 are attached to manufacture the display device 100.

Referring to FIG. 4C again, the conductive light shielding member 15 with the third hole TH3 having a fourth diameter D4 is preferentially aligned on the rear surface of the support member 20 and the conductive member 10 and the support member 20 may be adhered using the conductive light shielding member 15. According to the exemplary embodiment, a protective film may be further disposed on the rear surface of the conductive light shielding member 15. When the conductive light shielding member 15 is attached on the rear surface of the front member 90 along an inner side surface of the laminating unit, the protective film may protect the conductive light shielding member 15 from a physical force applied during the attaching process.

Referring to FIG. 4D, the conductive light shielding member 15 may be attached on the rear surface of the front member 90 along the inner side surface of the laminating unit by the physical force. For example, the physical force may be applied by utilizing air or an attachment jig. The conductive light shielding member 15 may be bonded to the inner side surface of the laminating unit and the rear surface of the front member 90 and may seal the inner side surface of the laminating unit and the rear surface of the front member 90 from the outside.

The exemplary embodiments of the present disclosure can also be described as follows:

According to an aspect of the present disclosure, there is provided a display device. The display device include a display panel including an active area in which a plurality of sub pixels is disposed and a sensor area which is disposed in the active area and has a first hole disposed therein, a front member disposed on a top surface of the display panel, a support member disposed on a rear surface of the display panel, a conductive member disposed on a rear surface of the support member and a conductive light shielding member which is disposed between the conductive member and the support member in a first region corresponding to the support member and covers an edge of a rear surface of the front member exposed by the first hole and an inner side surface of the first hole in a second region corresponding to an edge of the first hole.

The conductive light shielding member may include a plurality of conductive balls.

The conductive light shielding member may include a conductive film.

The conductive light shielding member may include a conductive fabric.

The conductive light shielding member may be configured to form a movement path of charges which move charges generated in the front member from an inner side surface of the first hole to between the support member and the conductive member.

The conductive light shielding member may comprise an adhesive material.

The conductive member may include a second hole which overlaps the first hole.

The display device may further include an additional light shielding member on the rear surface of the front member.

An end portion of the conductive light shielding member may be disposed on the additional light shielding member, in a region corresponding to the first hole.

The conductive light shielding member may include a first part disposed in the first region and a second part disposed in the second region. And a length of the second part may be longer than a length of an entire laminating unit disposed between the conductive light shielding member and the front member.

A difference between the length of the second part and the length of the entire laminating unit may be smaller than a radius of the first hole.

The laminating unit may include an optical layer, a touch layer, an encapsulation layer, the display panel, and the support member which are sequentially disposed.

The optical layer, the touch layer, the encapsulation layer, the display panel, and the support member may form a continuous interface in an inner side surface of the first hole.

The conductive light shielding member may be in contact with and cover inner side surfaces of the optical layer, the touch layer, the encapsulation layer, the display panel, and the support member.

According to another aspect of the present disclosure, there is provided a display device. The display device includes a display panel including an active area in which a plurality of sub pixels is disposed and a sensor area which is disposed in the active area and has a first hole disposed therein, a front member disposed on a top surface of the display panel, a support member disposed on a rear surface of the display panel, a conductive member disposed on a rear surface of the support member and a conductive light shielding member which includes a first part disposed on the rear surface of the support member and a second part which extends from an edge of the support member to an edge of a rear surface of the front member exposed by the first hole.

The conductive light shielding member may include a plurality of conductive balls.

The conductive light shielding member may include a conductive film.

The conductive light shielding member may include a conductive fabric.

The conductive light shielding member may be configured to form a movement path of charges which move charges generated in the front member from an inner side surface of the first hole to between the support member and the conductive member.

The conductive light shielding member may comprise an adhesive material.

According to another aspect of the present disclosure, there is provided a display device, comprising: a display panel; a front member disposed on one side of the display panel; a conductive member disposed on another side of the display panel; and a conductive light shielding member, wherein a first hole penetrates the first member and the display panel, and wherein the conductive light shielding member is disposed between the conductive member and the display panel and extends to the front member, and extends from a rear surface of the front member towards a central axis direction of the first hole.

The conductive light shielding member may include one of a plurality of conductive balls, a conductive film a conductive fabric, and may include an adhesive material.

A length of the conductive light shielding member in the central axis direction of the first hole may be smaller than a radius of the first hole.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including an active area;
a plurality of sub pixels disposed in the active area;
a sensor area disposed in the active area and having a first hole;
a front member disposed on a top surface of the display panel;
a support member disposed on a rear surface of the display panel;
a conductive member disposed on a rear surface of the support member; and
a conductive light shielding member disposed between the conductive member and the support member in a first region of the display panel corresponding to the support member, wherein the conductive light shielding member covers an edge of a rear surface of the front member exposed by the first hole of the sensor area and an inner side surface of the first hole of the sensor area in a second region of the display panel corresponding to an edge of the first hole.

2. The display device according to claim 1, wherein the conductive light shielding member includes a plurality of conductive balls.

3. The display device according to claim 1, wherein the conductive light shielding member includes a conductive film.

4. The display device according to claim 1, wherein the conductive light shielding member includes a conductive fabric.

5. The display device according to claim 1, wherein the conductive light shielding member is configured to form a movement path of charges to move charges generated in the front member from an inner side surface of the first hole to between the support member and the conductive member.

6. The display device according to claim 1, wherein the conductive light shielding member comprises an adhesive material.

7. The display device according to claim 1, wherein the conductive member includes a second hole which overlaps the first hole.

8. The display device according to claim 1, further comprising:
an additional light shielding member on the rear surface of the front member.

9. The display device according to claim 8, wherein an end portion of the conductive light shielding member is disposed on the additional light shielding member in a region of the display panel corresponding to the first hole.

10. The display device according to claim 1, wherein the conductive light shielding member includes a first portion disposed in the first region and a second portion disposed in the second region, and
a length of the second portion is greater than a length of an entire lamination stack disposed between the conductive light shielding member and the front member.

11. The display device according to claim 10, wherein a difference between the length of the second portion and the length of the entire lamination stack is less than a radius of the first hole.

12. The display device according to claim 10, wherein the lamination stack includes an optical layer, a touch layer, an encapsulation layer, the display panel, and the support member which are sequentially disposed.

13. The display device according to claim 12, wherein the optical layer, the touch layer, the encapsulation layer, the display panel, and the support member form a continuous interface in an inner side surface of the first hole.

14. The display device according to claim 12, wherein the conductive light shielding member is in contact with and covers inner side surfaces of the optical layer, the touch layer, the encapsulation layer, the display panel, and the support member.

15. A display device, comprising:
a display panel including an active area;
a plurality of sub pixels disposed in the active area;
a sensor area disposed in the active area and having a first hole;
a front member disposed on a top surface of the display panel;
a support member disposed on a rear surface of the display panel;
a conductive member disposed on a rear surface of the support member; and
a conductive light shielding member including a first portion disposed on the rear surface of the support member and a second portion extending from an edge of the support member to an edge of a rear surface of the front member exposed by the first hole.

16. The display device according to claim 15, wherein the conductive light shielding member includes a plurality of conductive balls.

17. The display device according to claim 15, wherein the conductive light shielding member includes a conductive film.

18. The display device according to claim 15, wherein the conductive light shielding member includes a conductive fabric.

19. The display device according to claim 15, wherein the conductive light shielding member is configured to form a movement path of charges to move charges generated in the front member from an inner side surface of the first hole to between the support member and the conductive member.

20. The display device according to claim 15, wherein the conductive light shielding member comprises an adhesive material.

21. A display device, comprising:
a display panel;
a front member disposed on a first side of the display panel;
a conductive member disposed on a second side of the display panel;
a conductive light shielding member; and
a first hole extending through the first member and the display panel,
wherein the conductive light shielding member is disposed between the conductive member and the display panel and extends to the front member, and wherein the conductive light shielding member extends from a rear surface of the front member towards a central axis direction of the first hole.

22. The display device according to claim 21, wherein the conductive light shielding member includes one of a plurality of conductive balls, a conductive film a conductive fabric, and includes an adhesive material.

23. The display device according to claim 21, wherein a length of the conductive light shielding member in the central axis direction of the first hole is less than a radius of the first hole.
